(19) United States
(12) Patent Application Publication
(10) Pub. No.: US 2025/0103761 A1
(43) Pub. Date: Mar. 27, 2025

(54) BIM OPERATION MANAGEMENT METHOD

(71) Applicants: KOREA LAND & HOUSING CORPORATION, Jinju-si (KR); KCMC Inc., Seoul (KR)

(72) Inventors: Dong Koo KWAK, Seoul (KR); Woo Chan KIM, Anyang-si (KR); Yeong Jun CHOI, Gwangju (KR); Yeong Ho LEE, Namyangju-si (KR)

(21) Appl. No.: 18/897,051

(22) Filed: Sep. 26, 2024

(30) Foreign Application Priority Data
Sep. 26, 2023 (KR) 10-2023-0129219

(51) Int. Cl. G06F 30/13

(52) U.S. Cl. CPC G06F 30/13

(57) ABSTRACT

The present invention relates to a building information modeling (BIM) operation management method, and more specifically, to a BIM operation program that can provide improved convenience to a user by directly viewing and checking data on a structure within a BIM 3D model management program without viewing a separate auxiliary program, and that allows simultaneous cross-editing by linking with a spreadsheet or document creation program where structure data is input when editing data in the BIM 3D model management program.

### CROSS-REFERENCE TO RELATED APPLICATION

This application claims under 35 U.S.C. § 119(a) the benefit of Korean Patent Application No. 10-2023-0129219 filed on Sep. 26, 2024, the entire contents of which are incorporated herein by reference.

### BACKGROUND OF THE INVENTION

### (a) Technical Field

The present invention relates to a building information modeling (BIM) operation management method, and more specifically, to a BIM operation management method that can check structure data.

### (b) Background Art

The content described in this section simply provides background information on the present invention and does not constitute the prior art.

When constructing a building, the entire building is first designed through 3D modeling, then the 3D modeling and process management are combined to establish a work breakdown structure (WBS), activities according to the object structure of the process are determined, and then a construction work is carried out. Normally, in order to construct a building, it is desirable to integrate and manage information into one system and systematically manage construction, manpower, time, and cost, or the like, and when the stages of each process are managed without being integrated with each other or when the entire process is managed manually, many errors are bound to occur and there are bound to be limitations. Building information modeling (BIM) refers to a 3D design technology that has recently become a hot topic in the construction industry, and an open BIM refers to BIM that uses international standards (IFC) to share data regardless of the type of software used.

Meanwhile, the structure includes various information such as a design reference code, a standard specification code, and a specialized specification, but there is a problem in that a manager cannot input or check information on the structure including multiple objects through the BIM program.

Therefore, there is a problem that a program that input the information on the structure has to be viewed separately and then the work has to be done using a separate BIM 3D model management program such as an Autodesk Navisworks program.

Various attempts are being made to solve this problem.

Korean Patent No. 0593716 relates to a four-dimensional construction management system and a method for providing construction management information using the same, and in order to provide a four-dimensional construction management system and a method for providing construction management information using the same, which allows users to easily search and utilize a relationship between a construction status, field performance, and construction schedule by combining a conventional process management system with three-dimensional visualized construction status data, the four-dimensional construction management system provides an architectural model and progress chart for each construction stage as four-dimensional data combining time and three-dimensional models according to the request of the user connected via the Internet or local network. The four-dimensional construction management system includes a server system including a portal page having a menu window for displaying a list of searchable data or displaying the types of data that can be input and including a database storing a process management table, a three-dimensional design model by construction stage, 4D data obtained by combining a process management table and a three-dimensional model of construction status into Virtual Reality (VR), and controlling display of 4D data searched according to a user's request or generating 4D data based on data input by a user and storing the 4D data in the database, and a client system having a communication means that can connect to the server system via the Internet or a local network.

As described above, in order to solve the problems of the conventional BIM program, some domestic and overseas related companies have conducted research on programs that improve the management of various data belonging to objects, but there are no programs available on the market, and even when there is a program available on the market, the cost-effectiveness of the program is not great, so the market competitiveness is low, and there are no cases of full-scale commercialization.

Therefore, the development of a BIM program that can solve the problems of the conventional technology as described above is required.

### SUMMARY OF THE INVENTION

The problems to be solved by the present invention are to supplement the shortcomings of the conventional technology mentioned above, and the objects of the present invention are as follows.

First, it is an object of the present invention to provide a BIM operation management method that can provide improved convenience to a user by directly viewing and checking data related to a structure within a BIM 3D model management program without viewing a separate auxiliary program.

Second, it is another object of the present invention to provide a BIM operation program that can be cross-edited simultaneously by linking with a spreadsheet or document creation program where structure data is input when editing data in the BIM 3D model management program.

Third, it is still another object of the present invention to provide a BIM operation program having improved compatibility with various programs by converting data into other program formats.

The objects of the present invention are not limited to the objects mentioned above, and other objects that are not mentioned can be clearly understood by those skilled in the art from the description below.

According to an aspect of the present invention, there is provided a building information modeling (BIM) operation management method provided through an API call command for a BIM 3D model management program utilized in a BIM field and performed by a computer processor, the BIM operation management method including: a structure data generation step of generating a structure data in which at least one of a design reference code, a standard specification code, and a specialized specification for a structure (facility) including multiple objects (models) is input in a spreadsheet or document creation program; a viewing step of viewing a 3D file or a BIM file for a specific structure on the BIM 3D model management program; an identity determination step of checking whether the specific structure in a file viewed in the structure viewing step on the BIM 3D model management program matches the structure in the spreadsheet or document creation program generated in the structure data generation step; and a structure data provision step of providing at least one of a design reference code, a standard specification code, and a specialized specification for the structure in the spreadsheet or document creation program to a user terminal using the BIM 3D model management program when the specific structure in the file viewed in the structure viewing step on the BIM 3D model management program in the identity determination step matches the structure in the spreadsheet or document creation program generated in the structure data generation step, and of not providing information on the mismatched structure in the spreadsheet or document creation program when the file for the specific structure viewed in the structure viewing step on the BIM 3D model management program in the identity determination step does not match with the structure in the spreadsheet or document creation program generated in the structure data generation step, wherein in the structure data generation step, when multiple structures exist, information on each structure is input into a separate sheet of the spreadsheet or document creation program, information on the multiple structures is managed by a single spreadsheet or document creation program file, and a sheet name of a sheet of the spreadsheet or document creation program file is the same as a structure code assigned to the specific structure, in the identity determination step, whether the specific structure viewed in the structure viewing step matches the structure of the structure data generation step is checked according to whether the structure code of the BIM 3D model management program matches with the sheet name of the sheet of the spreadsheet or document creation program file, and the structure code includes an internal code value including English letters, numbers, and special characters and an external exposure value including a name of the structure, and in the identity determination step, whether the specific structure viewed in the structure viewing step matches the structure of the structure data generation step is checked according to whether the external exposure value matches with the sheet name of the sheet of the spreadsheet or document creation program file, and when the number of items of information on the structure provided in the structure data provision step is equal to or less than a preset number, the structure data provision step provides all items of information on the structure to the user terminal, and when the number of items of information on the structure is equal to or more than a preset number, the structure data provision step provides an item of information selected to be equal to or less than a preset number to the user terminal. The BIM operation management further includes an automatic classification step of automatically classifying the selected items of the information by an AI when the number of items of information in the structure data provision step is equal to or more than the preset number, the automatic classification step including an acquisition step of acquiring and storing a screen of a display as an image at the moment when a screen on which the information on the structure is exposed is clicked by the user terminal, a classification step of setting a certain range as an area of interest based on a location of a point clicked by the user terminal based on the image acquired in the acquisition step and classifying remaining areas as an area of no interest, an accumulation step of accumulating and acquiring the screen image of the display at the moment when the screen on which the information on the structure is exposed is clicked by the user terminal by repeatedly accumulating the acquisition step and the classification step up to a preset reference value each time the screen on which the information on the structure is exposed is clicked by the user terminal, and a setting step of comparing areas set as the area of interest in a plurality of images and setting an information item on the structure exposed to the area of interest with the most overlap as the item of information to be selected in the structure data provision step.

Meanwhile, the BIM operation management may further include an editing step of adding, modifying, or deleting data in a structure data window output to the BIM 3D model management program in the structure data provision step, and when edited data is stored in the BIM 3D model management program, storing the edited data together in the spreadsheet or document creation program.

Additional solutions of the present invention will be partially explained in the following description, and can be partially easily checked from the description, or can be acquired by practicing the present invention.

Both the general description above and the detailed description below are merely exemplary and explanatory and do not limit the present invention described in the claims.

The effects of the present invention configured as above are as follows.

First, improved convenience can be provided to the user by directly viewing and checking data on the structure within the BIM 3D model management program without viewing a separate auxiliary program.

Second, when editing data in the BIM 3D model management program, cross-editing is possible simultaneously by linking with the spreadsheet or document creation program where the structure data is input.

Third, compatibility with various programs can be improved by converting data into other program formats.

The effects of the present invention are not limited to the effects mentioned above, and other effects not mentioned can be clearly understood by those skilled in the art from the description of the claims.

### BRIEF DESCRIPTION OF THE DRAWINGS

FIG. 1 is a flow chart according to one embodiment of the present invention.

FIG. 2 is a diagram illustrating an algorithm according to one embodiment of the present invention.

FIG. 3 is a diagram illustrating a screen where data input from a spreadsheet or document creation program is output from a BIM 3D model management program when selecting a structure according to one embodiment of the present invention.

FIG. 4 is a diagram illustrating a screen where data is linked and edited together in a spreadsheet or document creation program when editing data in a BIM 3D model management program according to one embodiment of the present invention.

### DETAILED DESCRIPTION

Hereinafter, specific embodiments of the present invention will be described in detail with reference to the attached drawings.

However, when describing a specific embodiment of the present invention, in a case where it is determined that a specific description of a related known function or configuration may unnecessarily obscure the gist of the present invention, the detailed description thereof will be omitted.

The above-described purposes, features, and advantages of the present invention will be made clearer through the following detailed description related to the attached drawings. However, the present invention may have various changes and may include various embodiments, and thus, specific embodiments are illustrated in the drawings and described in detail below.

When it is determined that a specific description of a known function or configuration related to the present invention may unnecessarily obscure the gist of the present invention, the detailed description will be omitted. In addition, the numbers used in the description of this specification are merely identifiers to distinguish one component from another.

In addition, a suffix “portion” for components used in the description below is only used or mixed to facilitate the writing of the specification, and does not have a distinct meaning or role in itself.

In addition, in the description below, a “user” may be interpreted as having the same meaning as a “user terminal”, and an “administrator” may be interpreted as having the same meaning as an “administrator terminal”.

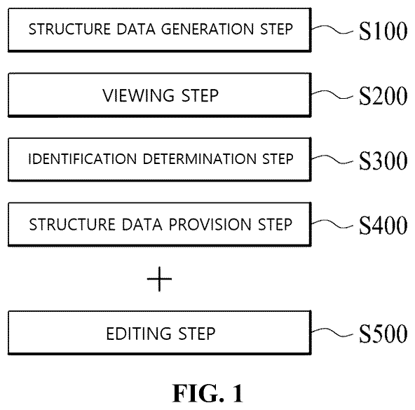

FIG. 1 is a flow chart according to one embodiment of the present invention.

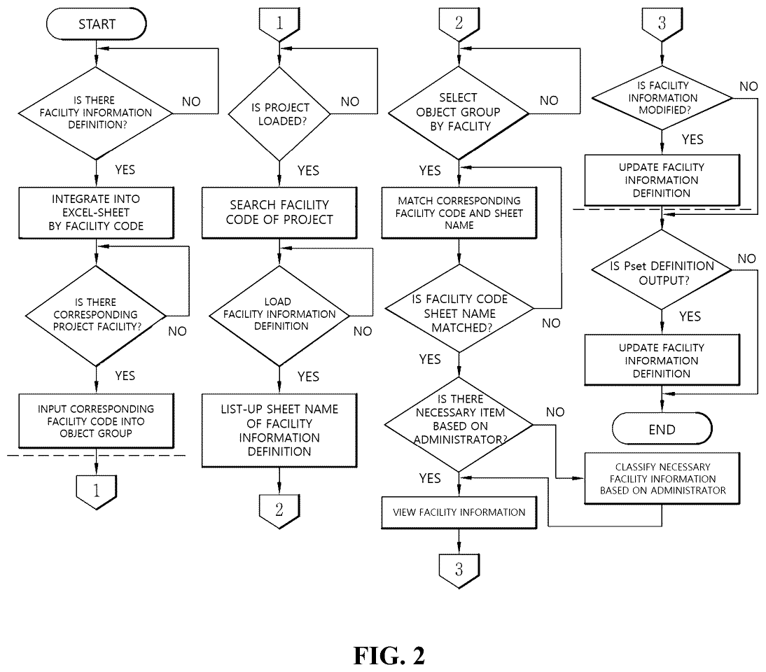

FIG. 2 is a diagram illustrating an algorithm according to one embodiment of the present invention.

As part of the API (3rd Party Program) of a BIM 3D model management program such as Autodesk Navisworks program utilized in a building information modeling (BIM) field, there is provided a BIM operation management method including a structure data generation step of generating a structure data in which at least one of a design reference code, a standard specification code, and a specialized specification for a structure (facility) including multiple objects (models) is input in a spreadsheet or document creation program, a viewing step of viewing a 3D file or a BIM file for a specific structure on the BIM 3D model management program, an identity determination step of checking whether the specific structure in a file viewed in the structure viewing step on the BIM 3D model management program matches the structure in the spreadsheet or document creation program generated in the structure data generation step, and a structure data provision step of providing information on the structure in the spreadsheet or document creation program to a user terminal using the BIM 3D model management program when the specific structure in the file viewed in the structure viewing step on the BIM 3D model management program in the identity determination step matches with the structure in the spreadsheet or document creation program generated in the structure data generation step, and of not providing information on the mismatched structure in the spreadsheet or document creation program when the file for the specific structure viewed in the structure viewing step on the BIM 3D model management program in the identity determination step does not match with the structure in the spreadsheet or document creation program generated in the structure data generation step.

In this case, when there are multiple structures, one BIM 3D model management program file is generated per structure, and a unique structure code is assigned to each structure so that one structure among multiple structures may be specified, and one BIM 3D model management program file may include the structure code.

In addition, when there are multiple structures, the structure data generation step can manage information on multiple structures with one spreadsheet or document creation program file by inputting information on each structure into a separate sheet of the spreadsheet or document creation program.

In addition, a sheet name of a sheet of the spreadsheet or document creation program file is the same as the structure code assigned to a specific structure, and in the identity determination step, it is possible to check whether the specific structure viewed in the structure viewing step matches the structure of the structure data generation step according to whether the structure code of the BIM 3D model management program matches with the sheet name of the sheet of the spreadsheet or document creation program file.

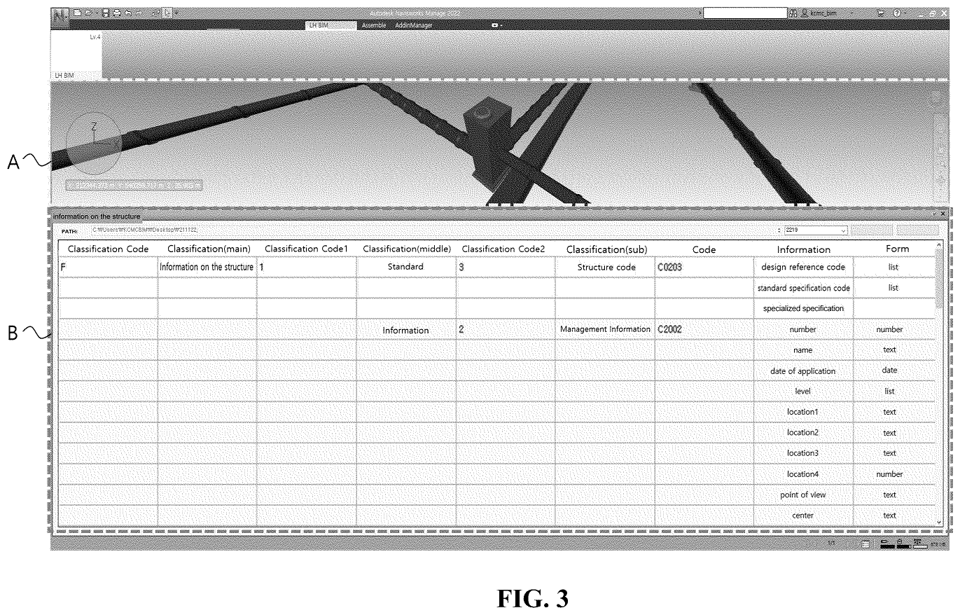

FIG. 3 is a diagram illustrating a screen where data input from a spreadsheet or document creation program is output from a BIM 3D model management program when selecting a structure according to one embodiment of the present invention.

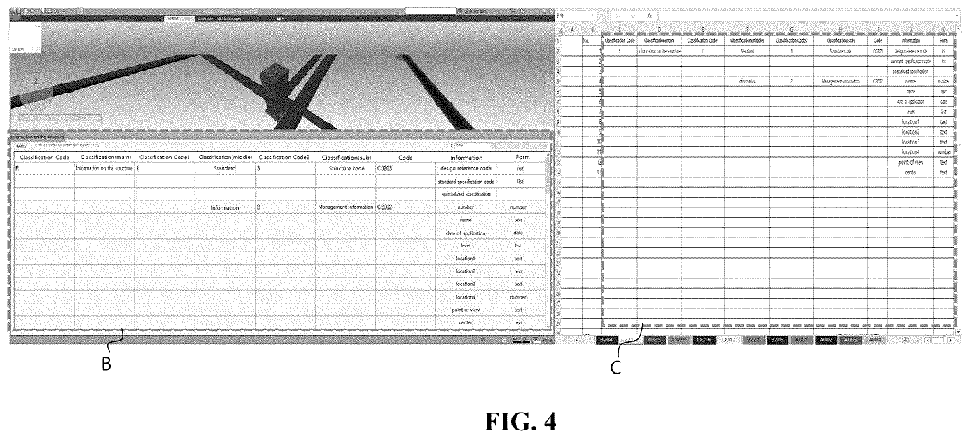

FIG. 4 is a diagram illustrating a screen where data is linked and edited together in a spreadsheet or document creation program when editing data in a BIM 3D model management program according to one embodiment of the present invention.

As illustrated in FIG. 3, when a specific structure is selected in a structure area A of a BIM 3D model management program, data input from a spreadsheet or document creation program can be output through a data area B at the bottom of the structure area A.

As illustrated in FIG. 4, when editing data output from the data area B of the BIM 3D model management program, it can be checked that it is automatically edited in a spreadsheet or document creation program C in conjunction with the editing of the data.

Meanwhile, in the structure data provision step, data may be added, modified, or deleted in a structure data window output to the BIM 3D model management program, and when storing the edited data in the BIM 3D model management program, an editing step can be included in which the edited data is stored together in the spreadsheet or document creation program.

At this time, the structure code includes an internal code value including English letters, numbers, and special characters and an external exposure value including the name of the structure, and in the identity determination step, it is possible to check whether the specific structure viewed in the structure viewing step matches the structure of the structure data generation step according to whether the external exposure value matches with the sheet name of the sheet of the spreadsheet or document creation program file.

Meanwhile, the internal code value can utilize a quantum random number generator.

The internal code value can be generated by the sum of a basic quantum random number generated by one attempt of the quantum random number generator and a twin quantum random number generated by a separate attempt from the quantum random number generator. Furthermore, the twin quantum random number may be attached to the front and back of the basic quantum random number to generate one internal code value (as a result, the internal code value is identical to the sum of the twin quantum random number-basic quantum random number-twin quantum random number).

In addition, when the number of items of information on the structure provided in the structure data provision step is equal to or less than a preset number, the structure data provision step provides all items of information on the structure to the user terminal, and when the number of items of information on the structure is equal to or more than a preset number, the structure data provision step provides an item of information selected to be equal to or less than a preset number to the user terminal.

At this time, the BIM operation management method may further include an automatic classification step of automatically classifying the selected items of the information by an AI when the number of items of information in the structure data provision step is equal to or more than the preset number.

Furthermore, the automatic classification step may include an acquisition step of acquiring and storing a screen of a display as an image at the moment when a screen on which the information on the structure is exposed is clicked by the user terminal, a classification step of setting a certain range as an area of interest based on a location of a point clicked by the user terminal based on the image acquired in the acquisition step and classifying the remaining area as an area of no interest, an accumulation step of accumulating and acquiring the screen image of the display at the moment when the screen on which the information on the structure is exposed is clicked by the user by repeatedly accumulating the acquisition step and the classification step up to a preset reference value each time the screen on which the information on the structure is exposed is clicked by the user, and a setting step of comparing areas set as the area of interest in a plurality of images and setting an information item on the structure exposed to the area of interest with the most overlap as the item of information to be selected in the structure data provision step.

Conventionally, in the method for automatically determining a preferred item, or the like, generally, counting is performed based on the number of times the user selects an item. However, in the automatic classification step according to the present invention, the preference is determined not by the number of times selected for a group, but by the number of times clicked on a specific area on the image.

The conventional item counting method can be most easily performed with a simple method, but the usage of the item counting method is extremely limited to determining preference, whereas the image and image area click determination method of the automatic classification step of the present invention can be seen as infinitely expandable to other things such as determining UI UX preference, counting number of items, or the like in addition to item preference.

Meanwhile, according to the present invention, a method for managing objects (models) that constitute a structure can be additionally provided.

The method for managing objects (models) is as follows.

The BIM operation management method is provided, including an object (model) generation step of generating several objects (models) that constitute a structure based on unique data provided by the administrator, a data storage step of inputting information corresponding to the object (model) by the user and classifying the information input by the user into upper categories such as basic attribute information and additional attribute information, a selection step of selecting one of the plurality of objects by the user, and an output step of outputting and providing information of the object stored in the data storage step to the user on one side of the object selected by the selection step.

In the above data storage step, data input by the user may be manually classified by the user, or alternatively, data may be automatically classified by determining an appropriate category based on AI, algorithms, or the like.

Meanwhile, various methods may be selected for displaying the data of the object selected in the output step, such as opening a new sub-window within the program or providing data on one side of the program window.

At this time, in the data storage step, the additional attribute information may be classified into an attribute-specific category according to a preset classification code and each piece of information input by the user may be classified according to an appropriate category, and in the output step, data belonging to a single attribute-specific category selected by the user among all information stored in the data storage step may be selected, and output and provided to the user, and data belonging to other attribute-specific categories not selected by the user may not be output and provided.

In addition, the basic attribute information of the data storage step may be classified into the intermediate categories of location information, management information, and product information, and the additional attribute information of the data storage step may be classified into the intermediate categories of a classification system, an object standard, object information, and application of details.

Meanwhile, other intermediate categories other than the classify system, object standard, object information, and the application of details may be added to the additional attribute information as needed.

Furthermore, the classification system among the intermediate categories may be classified into a subcategory including at least one of the following: division of labor, facility classification (main), facility classification (middle), facility classification(sub), a large type, a medium type, and a small type.

The object standard among the intermediate categories may be classified into a subcategory including at least one of the following: a minimum unit of the object, a reference point, a length, a height, a material, a concrete compressive strength, a patent number, a width, and a standard specification.

Among the intermediate categories, object information may be classified into subcategories that include at least one of the following: a name, a manhole type, a manhole height, a manhole number, a manhole type, a floor elevation, a top elevation, the number of connecting pipes, a name of connecting pipe, a roadway and sidewalk, a pipe diameter, a pipe length, a pipe name, a pipe type, and whether or not connecting pipes.

Among the intermediate categories, the application of details may be classified into subcategories that include at least one of the following: a name, a CHIAR BLOCK, a formwork, a stagging, ready-mix concrete casting (non-reinforced structure), ready-mix concrete casting (reinforced structure), manhole cover and pedestal installation, manhole stepping stone installation, a spacer, manpower mixing, invert mortar application, reinforcing bar processing and assembly, warning tape installation, reinforced concrete pipe cutting, sewer pipe drilling and joining, CCTV investigation inside sewer pipe, sewer pipe dredging, and fume pipe installation and joining.

More specifically, in the selection step, the user may select multiple objects (models) at the same time, and in the output step, data of multiple objects (models) selected in the selection step may be output and provided together in one window (when data of multiple objects (models) are provided in one window, data is distinguished by object (model) by a boundary Cell) or individually in different windows for each object (model) at the same time.

As a result, when selecting multiple objects (models), data for multiple objects can be checked and compared at the same time by classifying the selected information by boundary lines and outputting and providing the classified information.

Meanwhile, the output information first outputs and provides data belonging to basic attribute information, and when the user selects an additional attribute information category, outputting and provision of data belonging to basic attribute information can be stopped and data belonging to additional attribute information can be output and provided.

In addition, in the data storage step, individual drawings for each object (model) can be stored, and in the output step, drawings stored in the data storage step can be output and provided when the user desires.

In addition, the basic attribute information and additional attribute information of the single or multiple objects (models) selected in the above selection step may be converted into data according to another program file format and output and provided or printed by another program, including a conversion and transmission step of printing.

This embodiment merely exemplifies the technical idea of the present invention, and those with common knowledge in the technical field to which the present invention belongs may make various modifications and variations of this embodiment without departing from the essential characteristics of the present invention.

This embodiment is not intended to limit the technical idea of the present invention but to explain it, and therefore the scope of the rights of the present invention is not limited by this embodiment.

The scope of protection of the present invention should be interpreted by the scope of the claims, and all technical ideas recognized as equivalent or equivalent thereto should be interpreted as being included in the scope of the rights of the present invention.

What is claimed is:

1. A building information modeling (BIM) operation management method provided through an API call command for a BIM 3D model management program utilized in a BIM field and performed by a computer processor, the BIM operation management method comprising the steps of:
generating a structure data in which at least one of a design reference code, a standard specification code, and a specialized specification for a structure (facility) including multiple objects (models) is input in a spreadsheet or document creation program;
viewing a 3D file or a BIM file for a specific structure on the BIM 3D model management program;
determining an identity of checking whether the specific structure in a file viewed in the viewing of the structure on the BIM 3D model management program matches the structure in the spreadsheet or document creation program generated in the generating of structure data; and
providing a structure data of providing at least one of a design reference code, a standard specification code, and a specialized specification for the structure in the spreadsheet or document creation program to a user terminal using the BIM 3D model management program when a specific structure in a file viewed in the viewing of the structure on the BIM 3D model management program in the determining of the identity matches a structure in a spreadsheet or document creation program generated in the generating of the structure data, and of not providing information on the mismatched structure in the spreadsheet or document creation program when a file for a specific structure viewed in viewing of the structure on the BIM 3D model management program in the determining of the identity does not match a structure in the spreadsheet or document creation program generated in the generating of the structure data.

2. The BIM operation management method of claim 1, wherein in the generating of the structure data, when multiple structures exist, information on each structure is input into a separate sheet of the spreadsheet or document creation program, so that information on the multiple structures is managed by a single spreadsheet or document creation program file, and a sheet name of a sheet of the spreadsheet or document creation program file is the same as a structure code assigned to the specific structure,
in the determining of the identity, whether the specific structure viewed in the viewing of the structure matches the structure in the generating of the structure data is checked according to whether the structure code of the BIM 3D model management program matches with the sheet name of the sheet of the spreadsheet or document creation program file, wherein the structure code includes an internal code value including English letters, numbers, and special characters and an external exposure value including a name of the structure,
in the determining of the identity, whether the specific structure viewed in the viewing of the structure matches the structure in the generating of the structure data is checked according to whether the external exposure value matches the sheet name of the sheet in the spreadsheet or document creation program file, and
in the providing of the structure data, when the number of items of information on the structure provided in the providing of the structure data is equal to or less than a preset number, the providing of the structure data provides all items of information on the structure to a user terminal, and when the number of items of information on the structure is equal to or more than a preset number, the providing of the structure data provides an item of information selected to be equal to or less than a preset number to the user terminal.

3. The BIM operation management method of claim 2, further comprising automatically classifying the selected items of the information by an AI when the number of items of information in the providing of the structure data is equal to or more than the preset number, and
the automatically classifying includes:
acquiring of acquiring and storing a screen of a display as an image at the moment when a screen on which the information on the structure is exposed is clicked by the user terminal,
classifying of setting a certain range as an area of interest based on a location of a point clicked by the user terminal based on the image acquired in the acquiring, and classifying remaining areas as an area of no interest,
accumulating of accumulating and acquiring the screen image of the display at the moment when the screen on which the information on the structure is exposed is clicked by the user terminal by repeatedly accumulating the acquiring and the classifying up to a preset reference value each time the screen on which the information on the structure is exposed is clicked by the user terminal, and
setting of comparing areas set as the area of interest in a plurality of images, and setting an information item on the structure exposed to the area of interest with the most overlap as the item of information to be selected in the providing of the structure data.

4. The BIM operation management method of claim 2, further comprising editing data to be added, modified, or deleted in a structure data window output to the BIM 3D model management program in the providing of structure data, and when edited data is stored in the BIM 3D model management program, the edited data is stored together in the spreadsheet or document creation program.
